(19) United States
(12) Patent Application Publication
(10) Pub. No.: US 2013/0119450 A1
(43) Pub. Date: May 16, 2013

(54) NON-VOLATILE SEMICONDUCTOR STORAGE DEVICE

(71) Applicants: Shinya NAITO, Kanagawa (JP); Mitsutoshi NAKAMURA, Kanagawa (JP)

(72) Inventors: Shinya NAITO, Kanagawa (JP); Mitsutoshi NAKAMURA, Kanagawa (JP)

(21) Appl. No.: 13/678,780

(22) Filed: Nov. 16, 2012

(30) Foreign Application Priority Data
Nov. 16, 2011 (JP) 2011-250761

(51) Int. Cl. H01L 29/78

(52) U.S. Cl. CPC H01L 29/78
USPC 257/314

(57) ABSTRACT

Provided is a non-volatile semiconductor storage device including a memory cell which is disposed on a semiconductor substrate and where a control gate electrode is disposed on a charge storage layer, a select gate transistor where a select gate electrode is disposed between a source region and a drain region and which shares the source region with the memory cell, a first air gap which is disposed between the charge storage layers and between the source regions adjacent to each other in a word line direction and which is formed continuously over the memory cell and the select gate transistor adjacent to each other in a bit line direction so as to be concealed under the word line and under the select gate electrode, and a back-filling insulating film which back-fills an air gap between the drain electrodes adjacent to each other in the word line direction.

### CROSS-REFERENCE TO RELATED APPLICATIONS

This application is based upon and claims the benefit of priority from Japanese Patent Application No. 2011-250761 filed on Nov. 16, 2011; the entire contents of which are incorporated herein by reference.

### FIELD

Embodiments described herein relate generally to a non-volatile semiconductor storage device.

### BACKGROUND

In NAND-type flash memory, air gaps are disposed between memory cells in order to reduce parasitic capacitance between charge storage layers. In this case, if portions around select gate electrodes are covered with insulating materials, fringe electric field from the select gate electrodes is increased, so that threshold voltages of select gate transistors are decreased.

### BRIEF DESCRIPTION OF THE DRAWINGS

FIG. 1 is a schematic perspective diagram illustrating an example of a configuration of memory cells and select gate transistors of a non-volatile semiconductor storage device according to a first embodiment;

FIG. 2 is a schematic plan diagram illustrating an example of a configuration of a memory cell array of a non-volatile semiconductor storage device according to a second embodiment;

FIGS. 3A and 3B are cross-sectional diagrams illustrating an example of a non-volatile semiconductor storage device manufacturing method according to a third embodiment;

FIGS. 4A and 4B are cross-sectional diagrams illustrating an example of the non-volatile semiconductor storage device manufacturing method according to the third embodiment;

FIGS. 5A and 5B are cross-sectional diagrams illustrating an example of the non-volatile semiconductor storage device manufacturing method according to the third embodiment;

FIGS. 6A and 6B are cross-sectional diagrams illustrating an example of the non-volatile semiconductor storage device manufacturing method according to the third embodiment;

FIG. 7 is a cross-sectional diagram illustrating an example of the non-volatile semiconductor storage device manufacturing method according to the third embodiment;

FIGS. 8A and 8B are cross-sectional diagrams illustrating an example of the non-volatile semiconductor storage device manufacturing method according to the third embodiment;

FIGS. 9A to 9C are cross-sectional diagrams illustrating an example of the non-volatile semiconductor storage device manufacturing method according to the third embodiment;

FIGS. 10A to 10C are cross-sectional diagrams illustrating an example of the non-volatile semiconductor storage device manufacturing method according to the third embodiment;

FIGS. 11A to 11C are cross-sectional diagrams illustrating an example of the non-volatile semiconductor storage device manufacturing method according to the third embodiment;

FIGS. 12A to 12C are cross-sectional diagrams illustrating an example of the non-volatile semiconductor storage device manufacturing method according to the third embodiment.

FIGS. 13A to 13C are cross-sectional diagrams illustrating an example of the non-volatile semiconductor storage device manufacturing method according to the third embodiment;

FIGS. 14A to 14C are cross-sectional diagrams illustrating an example of the non-volatile semiconductor storage device manufacturing method according to the third embodiment;

FIGS. 15A to 15C are cross-sectional diagrams illustrating an example of the non-volatile semiconductor storage device manufacturing method according to the third embodiment;

FIGS. 16A to 16C are cross-sectional diagrams illustrating an example of a non-volatile semiconductor storage device manufacturing method according to a fourth embodiment;

FIGS. 17A to 17C are cross-sectional diagrams illustrating an example of a non-volatile semiconductor storage device manufacturing method according to a fifth embodiment;

FIG. 18 is a schematic perspective diagram illustrating a configuration of memory cells and select gate transistors of a non-volatile semiconductor storage device according to a sixth embodiment;

FIG. 19 is a schematic plan diagram illustrating an example of a configuration of a memory cell array of a non-volatile semiconductor storage device according to a sixth embodiment;

FIG. 20 is a plan diagram illustrating an example of a resist pattern arrangement method during formation of an air gap AG1 of FIG. 19; and

FIG. 21 is a cross-sectional diagram taken along line A-A of FIG. 19 as an example.

### DETAILED DESCRIPTION

In general, according to one embodiment, a non-volatile semiconductor storage device includes a memory cell, a select gate transistor, an air gap, and a back-filling insulating film. The memory cell is installed on a semiconductor substrate, and a control gate electrode is installed on a charge storage layer. In the select gate transistor, a select gate electrode is installed between a source region and a drain region, and the source region is shared with the memory cell. The air gap is disposed between the charge storage layers and between the source regions adjacent to each other in a word line direction and is formed continuously over the memory cell and the select gate transistor adjacent to each other in a bit line direction so as to be concealed under the word line and under the select gate electrode. The air gap between the drain regions adjacent to each other in the word line direction is back-filled by a back-filling insulating film.

Hereinafter, the non-volatile semiconductor storage device according to the embodiments will be described with reference to the drawings. In addition, the present invention is not limited to the embodiments. In addition, in the description, the up/down and left/right directions indicate relative directions in the case where the surface of the semiconductor substrate to be described below on which the memory cells are formed is faced up. In other words, in some cases, the direction in the description may be different from that with respect to the direction of the gravitational acceleration.

### First Embodiment

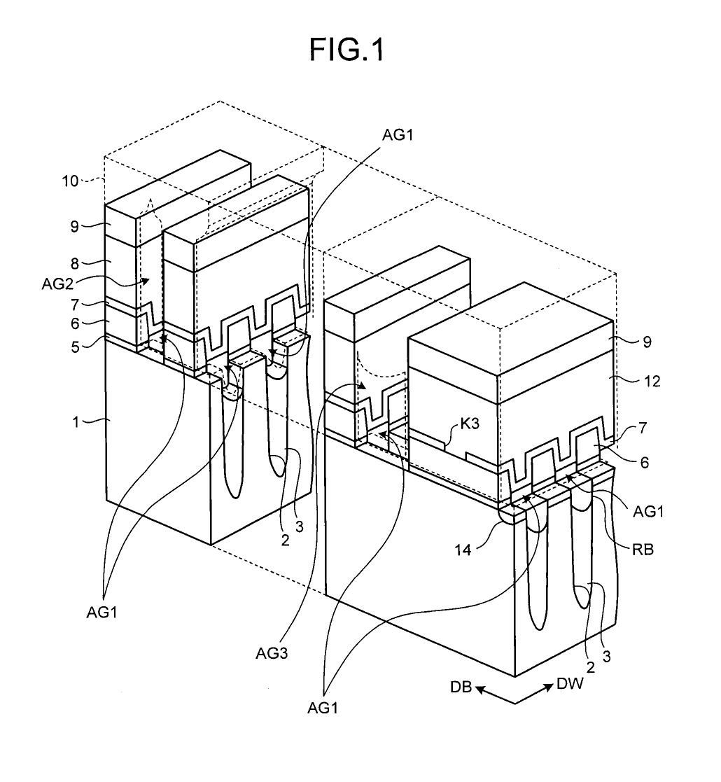

FIG. 1 is a schematic perspective diagram illustrating an example of a configuration of memory cells and select gate transistors of a non-volatile semiconductor storage device according to a first embodiment.

In FIG. 1, a plurality of trenches 2 are disposed in the DW direction in the semiconductor substrate 1 to extend along the bit line direction DB. Active areas of the memory cell and the select gate transistor formed in the semiconductor substrate 1 are separated by the trench 2. In addition, the active areas of the memory cell denote a channel region of a memory transistor installed in the memory cell and regions (for example, a source region and a drain region) between memory cells connected in series. The active areas of the select gate transistor denote a channel region, a source region, and a drain region of the select gate transistor. In addition, the source region of the select gate transistor may be shared as the source region of the memory cell adjacent to the select gate transistor. At this point, the memory cell adjacent to the select gate transistor may be a dummy memory cell (the same as the subsequent embodiments). In addition, a material of the semiconductor substrate 1 may be selected from, for example, Si, Ge, SiGe, SiC, SiSn, PbS, GaAs, InP, GaP, GaN, GaInAsP, ZnSe, or the like.

In addition, a burying insulating film 3 is buried in the trench 2. In addition, the burying insulating film 3 may be configured with, for example, a CVD oxide film, a silicon oxide film series such as an ALD oxide film or a CVD oxide film, or an inorganic polymer such as an SOG oxide film which is soluble in an organic solvent. In addition, the burying insulating film buried in the trench 2 may not necessarily be configured in a one-layer structure, but it may be configured with two layers or more.

In addition, in the active area of the memory cell on the semiconductor substrate 1, a charge storage layer 6 is formed for each memory cell through a tunnel insulating film 5. In the embodiment, the case where the charge storage layer 6 is configured as a floating gate electrode will be described. In addition, the charge storage layer 6 may be configured by using a charge trap film which is made of a silicon nitride film or like. In addition, the tunnel insulating film 5 may be configured by using, for example, a thermal oxide film or a thermal oxide nitride film. Alternatively, the tunnel insulating film 5 may be configured by using a CVD oxide film or a CVD oxide nitride film. Alternatively, the tunnel insulating film 5 may be configured by using insulating films interposing Si or an insulating film where Si is buried in a dot shape. The charge storage layer 6 may be configured by using polycrystalline silicon doped with N-type impurities or P-type impurities or a metal film or a poly-metal film using Mo, Ti, W, Al, Ta, or the like.

A control gate electrode 8 extends along the word line direction DW and is disposed on the charge storage layer 6 through an inter-electrode insulating film 7. In addition, the control gate electrode 8 may constitute a portion of a word line. Herein, in order to improve a coupling ratio between the charge storage layer 6 and the control gate electrode 8, the control gate electrode 8 may be formed so as to be in contact with a side wall of the DW side of the charge storage layer 6.

In addition, the charge storage layer 6 is formed in the active area of the select gate transistor on the semiconductor substrate 1 through the tunnel insulating film 5. In addition, the select gate electrode 12 is formed on the charge storage layer 6 to extend along the word line direction DW through the inter-electrode insulating film 7. The charge storage layer 6 and the select gate electrode 12 are collectively referred to as a “select gate electrode” in some cases. Herein, the opening K3 is formed in the inter-electrode insulating film 7 on the charge storage layer 6 of the select gate transistor, and the charge storage layer 6 is in contact with the select gate electrode 12 through the opening K3 of the inter-electrode insulating film 7. In addition, a high-concentration diffusion layer 14 is formed in the drain region of the select gate transistor. Herein, since the charge storage layer 6 of the select gate transistor is separated by the trench 2, the select gate transistor is formed for each semiconductor substrate 1 which is separated by the trench 2. In addition, the select gate electrode 12 is configured to extend along the DW direction and functions as a common gate electrode of the select gate transistors which are adjacent in the DW direction.

A silicide layer 9 is formed on the control gate electrode 8 and the select gate electrode 12, and a cover insulating film 10 is formed on the silicide layer 9. In addition, the inter-electrode insulating film 7 may be configured by using, for example, a silicon oxide film or a silicon nitride film. Alternatively, the inter-electrode insulating film 7 may be configured in a stacked structure of a silicon oxide film and a silicon nitride film such as an ONO film. Alternatively, the inter-electrode insulating film 7 may be configured by using a high dielectric film such as aluminum oxide or hafnium oxide or in a stacked structure of a low dielectric film and a high dielectric film such as a silicon oxide film or a silicon nitride film. The control gate electrode 8 and the select gate electrode 12 may be configured by using polycrystalline silicon doped with N-type impurities or P-type impurities. Alternatively, the control gate electrode 8 and the select gate electrode 12 may be configured by using a metal film or a poly-metal film using Mo, Ti, W, Al, Ta, or the like. In the case where the control gate electrode 8 and the select gate electrode 12 are configured by using a metal film or a poly-metal film, the silicide layer 9 may not be provided. The silicide layer 9 may be configured by using, for example, CoSi, NiSi, PtSi, WSi, MoSi, or the like. In addition, the cover insulating film 10 may be configured by using, for example, a silicon oxide film.

Herein, a portion of the upper portion of the burying insulating film 3 buried in the trench 2 is removed, so that an air gap AG1 is formed between the charge storage layers 6 adjacent to each other in the word line direction DW. The air gap AG1 is formed so as to penetrate into the upper portion of the trench 2, so that the bottom of the air gap AG1 reaches the position deeper than the lower surface of the charge storage layer 6. In addition, the air gap AG1 is formed continuously along the trench 2 so as to be concealed under the control gate electrode 8 and the select gate electrode 12, so that the air gap AG1 reaches the vicinity of the portion between the drain regions of the select gate transistors. In addition, the air gap AG1 is back-filled by the back-filling insulating film RB between the drain regions of the select gate transistor.

In other words, the upper surface of the burying insulating film 3 which is formed in the trench 2 is under the control gate electrode 8 so as to be lower than the upper surface of the semiconductor substrate 1, and the upper surface of the burying insulating film 3 is under the select gate electrode 12 so as to be lower than the upper surface of the semiconductor substrate 1. In addition, the lower surface of the control gate electrode 8 which is positioned on the upper surface of the trench 2 is higher than the upper surface of the semiconductor substrate 1, and the lower surface of the select gate electrode 12 which is positioned on the upper surface of the trench 2 is higher than the upper surface of the semiconductor substrate 1. In addition, with respect to the portion between the source regions of the memory cells and portion between the drain regions of the memory cells, the upper surface of the burying insulating film 3 is lower than the upper surface of the semiconductor substrate 1. In addition, with respect to the portion between the source regions of the select gate transistors, the upper surface of the burying insulating film 3 is lower than the upper surface of the semiconductor substrate 1.

Therefore, the air gap AG1 is positioned between the charge storage layers 6, the tunnel insulating films 5, the upper portion of the source regions or the drain regions of the memory cell, and the upper portion of the source regions of the select gate transistor.

In addition, the cover insulating film 10 is formed over the portion between the control gate electrodes 8 so as not to entirely bury the portion between the charge storage layers 6 and is formed over the portion between the control gate electrode 8 and the select gate electrode 12. Therefore, the air gap AG2 is formed between the charge storage layers 6 of the memory cells adjacent to each other in the bit line direction DB, and the air gap AG3 is formed between the charge storage layers 6 of the memory cell and the select gate transistor. In addition, the air gap AG2 may be formed to be asymmetric in the up/down direction, and the upper end thereof may have a pinnacled shape. In addition, the upper end of the air gap AG2 may be formed to be higher than the control gate electrode 8 or the silicide layer 9 of the memory cells adjacent to each other in the bit line direction DB. As a result, it is possible to greatly reduce interference of an electric field generated between the adjacent cells. In addition, the air gap AG1 and the air gap AG2 are connected to each other. The air gap AG1 and the air gap AG2 may be formed integrally.

In addition, the air gap AG3 may be formed between the select gate electrode 12 of the memory cell and the select gate electrode 12 adjacent to each other in the bit line direction DB. As a result, it is possible to greatly reduce interference of an electric field generated from the select gate electrodes 12. In addition, the air gap AG1 and the air gap AG3 are connected to each other. The air gap AG1 and the air gap AG3 may be formed integrally.

In addition, the lower surface of the back-filling insulating film RB between the memory cells in the bit line direction DB is positioned to be higher than the upper surface of the silicide layer 9 of the memory cell. In addition, the lower surface of the back-filling insulating film RB between the memory cell and the select gate transistor in the bit line direction DB is positioned to be lower than the upper surface of the silicide layer 9 of the memory cell of the select gate transistor. In other words, the lower surface of the back-filling insulating film RB between the memory cells is positioned to be higher than the lower surface of the back-filling insulating film RB between the memory cell and the select gate transistor.

### Second Embodiment

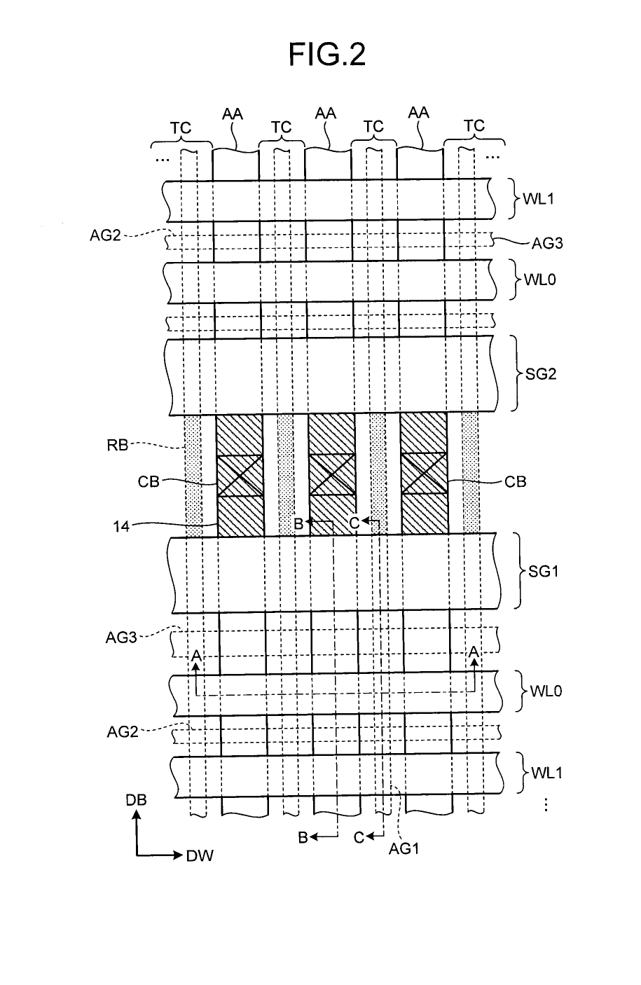

FIG. 2 is a schematic plan diagram illustrating an example of a configuration of a memory cell array of a non-volatile semiconductor storage device according to a second embodiment

In FIG. 2, a plurality of trenches TC are formed in the word line direction DW to be extended in the bit line direction DB, and the active area AA is separated by the trenches TC. In addition, the word lines WL0, WL1, . . . , which are extended in the word line direction DW, are formed in the bit line direction DB. The memory cells are formed at the intersections of the active area AA and the word lines WL0, WL1, . . . . In addition, the select gate electrodes SG1 and SG2 are formed to be extended in the word line direction DW. The gate electrodes of the select gate transistors are formed at the intersections of the active area AA and the select gate electrodes SG1 and SG2. Next, a high-concentration diffusion layer 14 is formed on the active area AA between the select gate electrodes SG1 and SG2, and a bit line contact CB is formed on the high-concentration diffusion layer 14.

In addition, the air gap AG1 is formed along the trench TC in the bit line direction DB. The air gap AG1 is formed continuously along the trench 2 so as to be concealed under the word lines WL0, WL1, . . . and the select gate electrodes SG1 and SG2, so that the air gap AG1 reaches the portion between the drain regions of the select gate transistor. In addition, the air gap AG2 is formed between the word lines WL0, WL1, . . . in the word line direction DW. In addition, the air gap AG3 is formed between the word line WL0 and the select gate electrode SG1. In addition, the air gap AG1 is back-filled by the back-filling insulating film RB between the drain regions of the select gate transistor. In addition, the air gap is not formed between the drain regions of the select gate transistor. In other words, the portion between the drain regions of the select gate transistors is buried by an insulating film including the back-filling insulating film RB.

Herein, since the air gaps AG1 and AG2 (for example, air having specific dielectric constant of about 1) are disposed between the charge storage layers 6, it is possible to reduce parasitic capacitance between the charge storage layers 6 in comparison with the case where an insulating material (for example, a silicon oxide film having specific dielectric constant of 3.9) is buried between the charge storage layers 6. Therefore, it is possible to reduce interference of an electric field generated between the adjacent cells due to the parasitic capacitance between the charge storage layers 6, so that it is possible to reduce a width of distribution of a threshold voltage of the cell transistor.

In addition, the air gap AG1 is formed continuously formed along the trench 2 so as to be concealed under the control gate electrode 8, so that it is possible to reduce fringe capacitance between the charge storage layer 6 and the semiconductor substrate 1. Therefore, in comparison with the case where there is no air gap AG1, the capacitance of the gate insulating film 5 can be reduced, so that it is possible to decrease a write voltage.

In addition, since the air gap AG1 is back-filled by the back-filling insulating film RB between the drain regions of the select gate transistor, when the high-concentration diffusion layer 14 is to be formed in the drain regions of the select gate transistor, it is possible to prevent impurities from penetrating the back-filling insulating film 3 adjacent to the drain region of the select gate transistor to reach the semiconductor substrate 1 (the bottom of the trench 2). In other words, the impurity of the semiconductor substrate 1 (first area) which is located at the bottom of the trench 2 adjacent to the drain region of the select gate transistor is hardly detected. In addition, in the case of the semiconductor substrate 1 (second area) which is located at the bottom of the trench 2 adjacent to the source region of the select gate transistor, the first area and the second area have almost the same impurity concentration. In addition, the type of the impurities of the first area and the second area described herein is the same as that of the high-concentration diffusion layer 14.

For example, in some cases, during a write operation, a different potential difference may be applied between the drain regions of the select transistors adjacent to each other in the DW direction. At this time, in the case where the impurity concentration of the first area is high, punch through occurs between the drain regions of the select transistors adjacent to each other. As a result, it is difficult to accurately write data in the memory cell.

On the other hand, in the embodiment, since the impurity concentration of the first area is relatively low, punch through hardly occurs. In addition, in the second area, since potential drop occurs due to the channels of the select gate transistors, the potential difference between the source regions of the select gate transistors is not increased by the potential difference between the drain regions of the select gate transistors.

Therefore, it is possible to suppress punch through between the drain regions of the select gate transistors and to decrease a fringe electric field generated from the select gate electrode 12.

### Third Embodiment

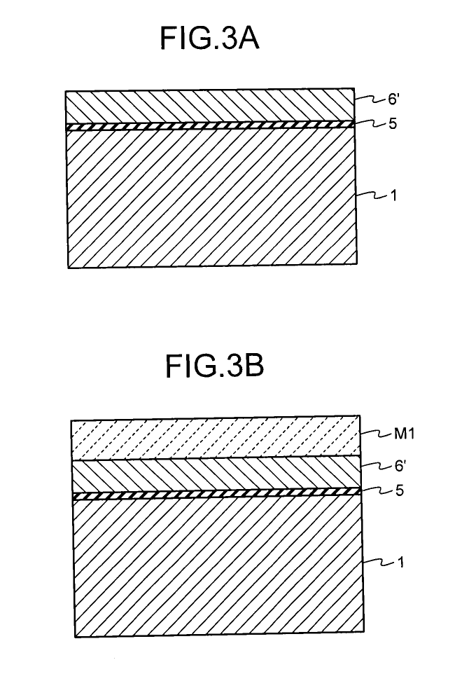

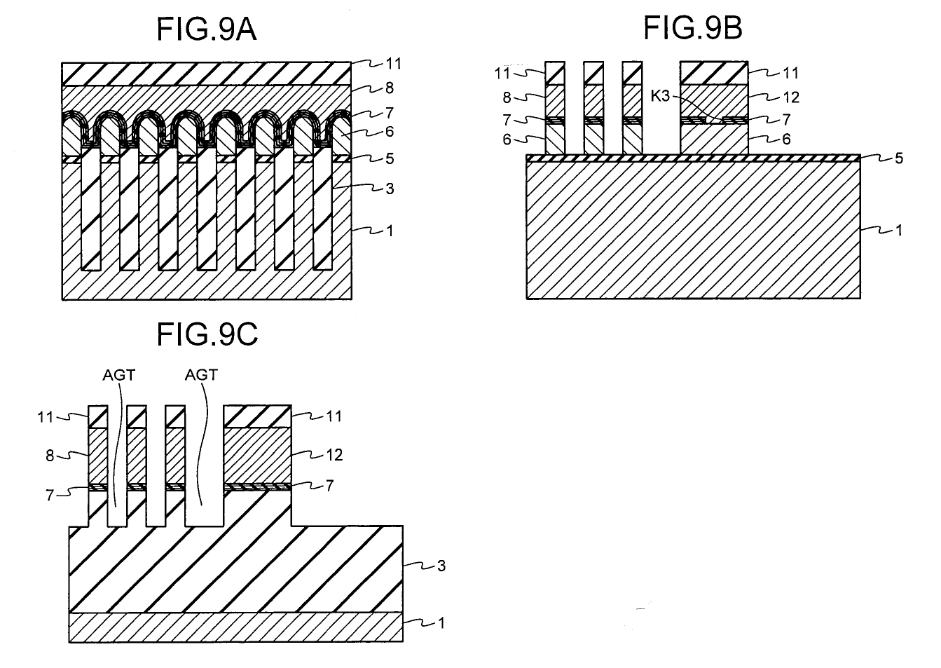

FIGS. 3A to 6A, FIGS. 3B to 6B, FIG. 7, FIG. 8A, FIG. 8B, FIGS. 9A to 15A, FIGS. 9B to 15B, FIGS. 9C to 15C are cross-sectional diagrams illustrating an example of a non-volatile semiconductor storage device manufacturing method according to a third embodiment. In addition, FIGS. 3A to 6A, FIG. 7, and FIGS. 9A to 15A are diagrams taken along line A-A of FIG. 2 as an example; FIGS. 3B to 6B, FIGS. 8A and 8B, and FIGS. 9B to 15B are diagrams taken along line B-B of FIG. 2; and FIGS. 9C to 15C are diagrams taken along line C-C of FIG. 2 as an example.

In FIG. 3A, a tunnel insulating film 5 is formed on the semiconductor substrate 1 by using a thermal oxidation method or the like. Next, a charge storage layer material 6′ is formed on the tunnel insulating film 5 by using a CVD method or the like.

As illustrated in FIG. 3B, a hard mask M1 is formed on the charge storage layer material 6′ by using a CVD method or the like. In addition, the hard mask M1 may be configured by using, for example, a silicon oxide film or a silicon nitride film.

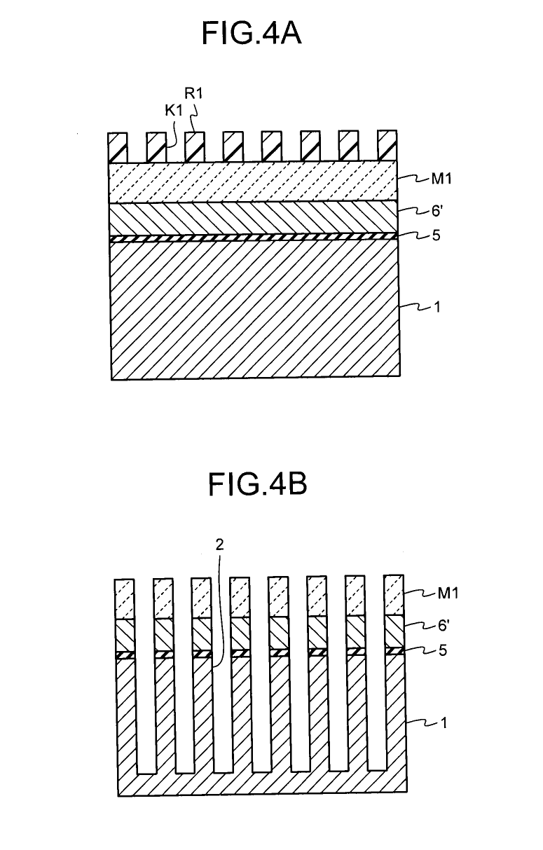

As illustrated in FIG. 4A, a resist pattern R1 where the opening K1 is formed is formed on the hard mask M1 by using a photolithography technique.

As illustrated in FIG. 4B, the hard mask M1 is patterned by using the resist pattern R1 as a mask, and after that, the charge storage layer material 6′, the tunnel insulating film 5, and the semiconductor substrate 1 are etched by using the hard mask M1 as a mask, so that the trench 2 is formed on the semiconductor substrate 1.

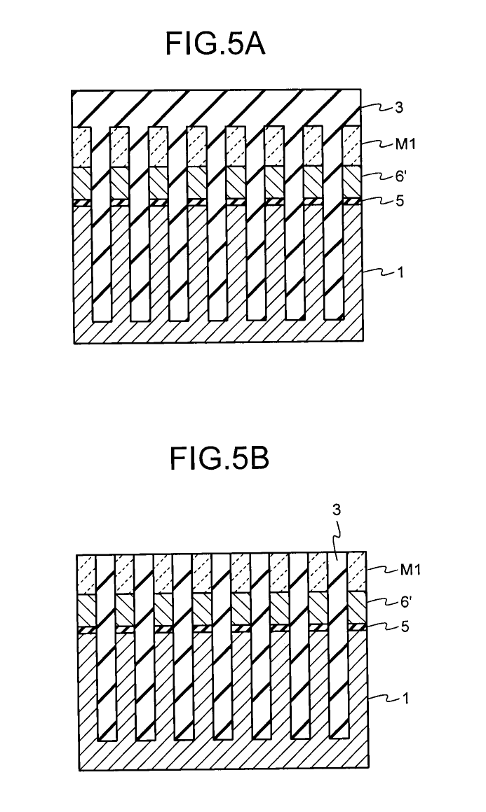

As illustrated in FIG. 5A, a burying insulating film 3 is formed on the hard mask M1 by using a CVD method, an SOG (coat) method, or the like so that the entire trench 2 is buried.

As illustrated in FIG. 5B, by using a CMP method or the like, the upper surface of the burying insulating film 3 is planarized, and the upper surface of the hard mask M1 is exposed.

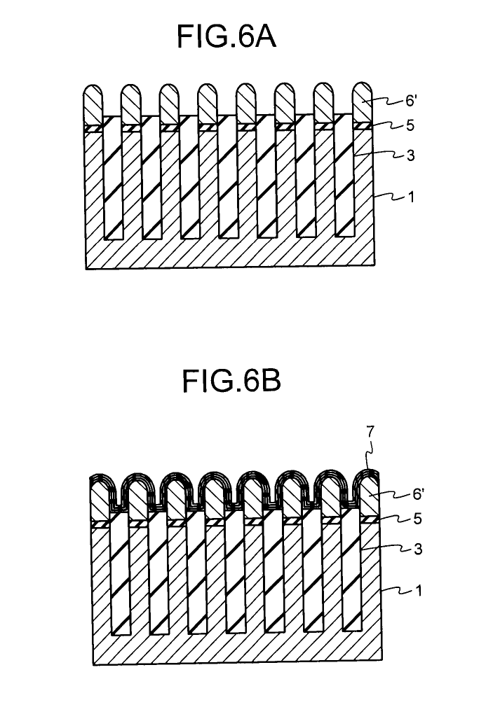

As illustrated in FIG. 6A, the hard mask M1 is removed by using a wet etching method or the like. In addition, in the case where the hard mask M1 is configured by using a silicon nitride film, a chemical solution of the wet etching may be a hot phosphoric acid. Next, by using anisotropic etching such as RIE, a portion of the burying insulating film 3 is removed, and a portion of the side wall of the charge storage layer material 6′ is exposed. In addition, in the case where a portion of the side wall of the charge storage layer material 6′ is exposed, it is preferable that the upper surface of the burying insulating film 3 is allowed to remain so as to be higher than the upper surface of the tunnel insulating film 5. In addition, in the case where the burying insulating film 3 is an SOG oxide film, a portion of the burying insulating film 3 may be removed by using wet etching using a rare hydrofluoric acid.

As illustrated in FIG. 6B, an inter-electrode insulating film 7 is formed on the charge storage layer material 6′ by using a CVD method or the like so that the side wall of the charge storage layer material 6′ is covered. In addition, the inter-electrode insulating film 7 may be configured to have a multi-layered structure of, for example, an ONO film. Herein, an opening K3 may be formed on the inter-electrode insulating film 7 at the position which is coincident with the charge storage layer 6 of the select gate transistor.

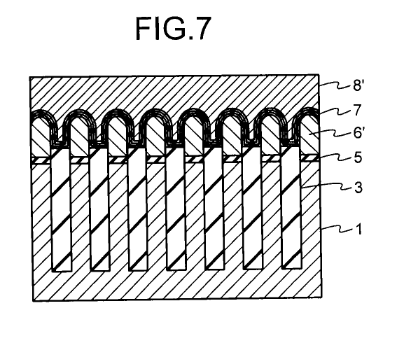

As illustrated in FIG. 7, a control gate electrode material 8′ is formed on the inter-electrode insulating film 7 by using a CVD method or the like.

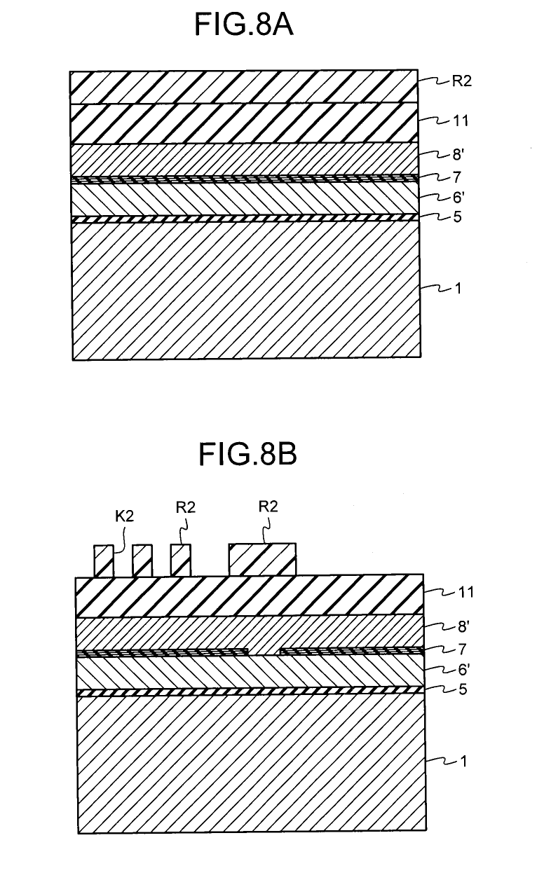

As illustrated in FIG. 8A, a cap insulating film 11 is formed on the control gate electrode material 8′ by using a CVD method or the like. In addition, the cap insulating film 11 may be configured by using, for example, a silicon oxide film or a silicon nitride film. Next, a resist film R2 is applied on the cap insulating film 11 by using a spin coat method or the like.

As illustrated in FIG. 8B, an opening K2 is formed on the resist film R2 by using a photolithography technique or the like.

As illustrated in FIGS. 9A to 9C, the cap insulating film 11 is patterned by using the resist film R2 where the opening K2 is formed as a mask, and after that, the control gate electrode material 8′, the inter-electrode insulating film 7, and the charge storage layer material 6′ are etched by using the cap insulating film 11 as a mask, so that the charge storage layer 6 separated for each memory cell is formed, and the control gate electrode 8 and the select gate electrode 12 which are disposed on the charge storage layer 6 through the inter-electrode insulating film 7 to be extended in the word line direction are formed. Herein, after the formation of the inter-electrode insulating film 7 before the formation of the control gate electrode material 8′, the select gate electrode 12 is allowed to be in contact with the charge storage layer 6 under the inter-electrode insulating film 7 through the opening K3 formed in the inter-electrode insulating film 7. Herein, the upper surface of the burying insulating film between the active areas AA is allowed to be lower than the upper surface of the semiconductor substrate 1, so that the trench AGT is formed.

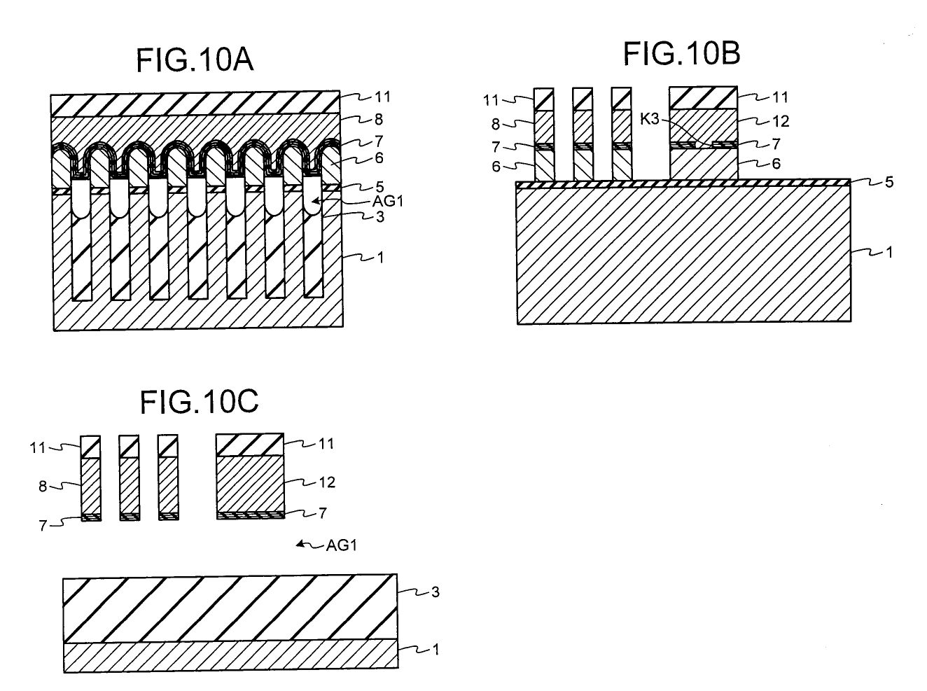

As illustrated in FIGS. 10A to 10C, a portion of the burying insulating film 3 is removed along the trench 2 by using a wet etching method or the like, so that the air gap AG1 is formed between the charge storage layers 6 adjacent to each other in the word line direction DW. At this time, a wet etchant is infiltrated from the trench AGT, so that the air gap AG1 is formed continuously formed along the trench 2 so as to be concealed under the control gate electrode 8 and the select gate electrode 12.

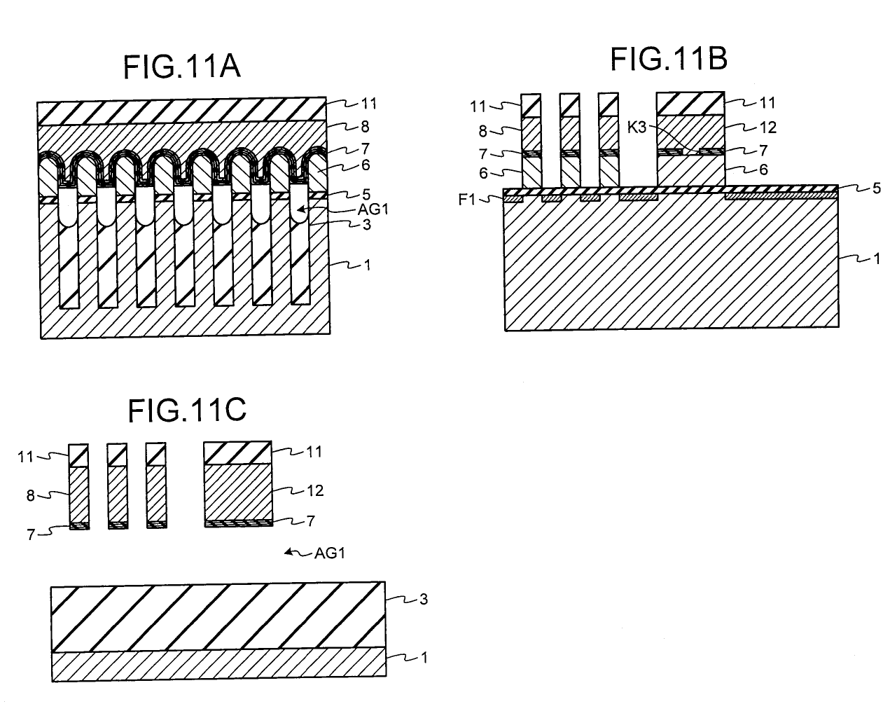

As illustrated in FIGS. 11A to 11C, a low-concentration diffusion layer F1 is formed on the source regions and the drain regions of the memory cell and the select gate transistor by selectively implanting impurity ions into the semiconductor substrate 1. Herein, since the low-concentration diffusion layer F1 is formed by low-acceleration, low-concentration ion implantation, a small amount of impurities penetrates the burying insulating film 3 to reach the semiconductor substrate 1 between the active areas AA.

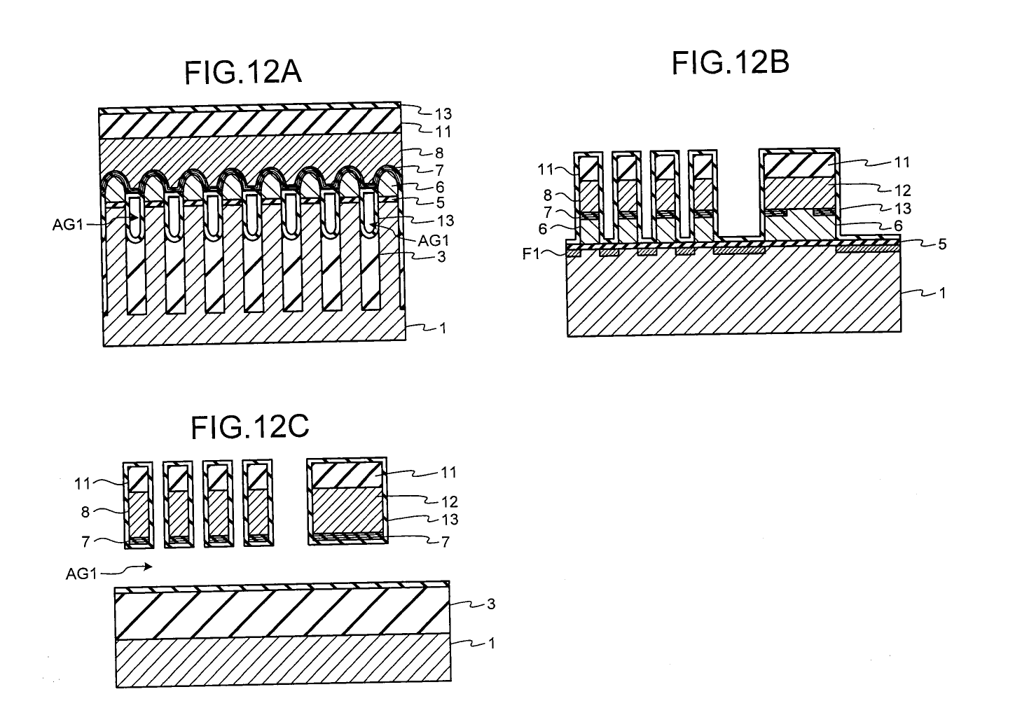

As illustrated in FIGS. 12A to 12C, a spacer insulating film 13 is formed to cover the entire exposed surface by using a CVD method or the like. In addition, the spacer insulating film 13 may be configured by using, for example, a silicon oxide film.

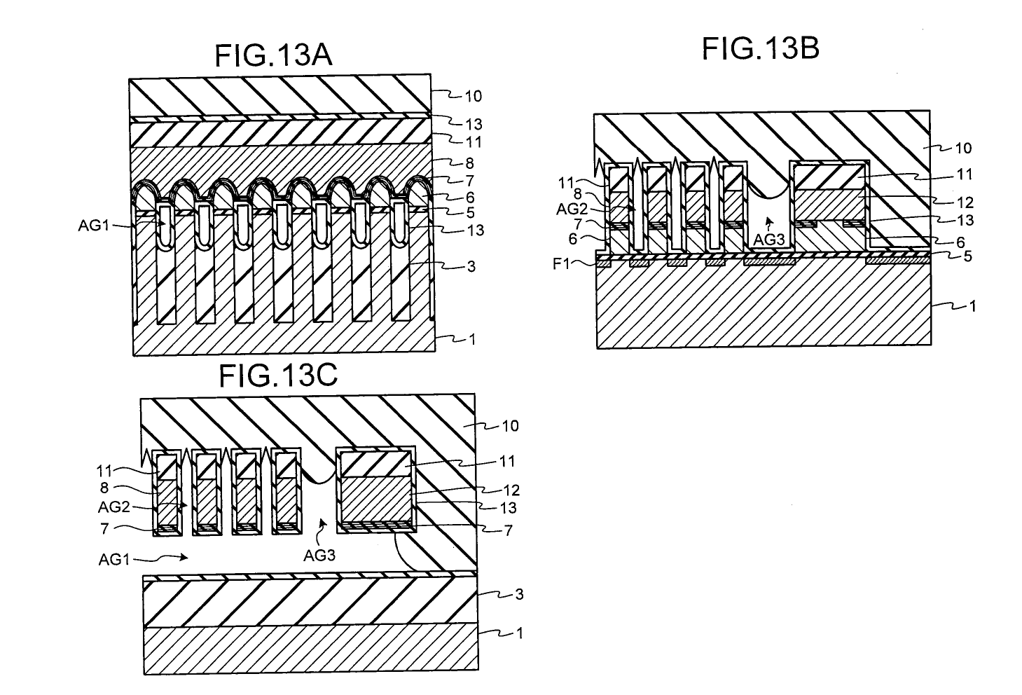

As illustrated in FIGS. 13A to 13C, by using a plasma CVD method or the like, the cover insulating film 10 is formed over the portions between the control gate electrodes 8 and between the control gate electrode 8 and the select gate electrode 12, and the air gaps AG2 and AG3 are formed between the charge storage layers 6 adjacent to each other in the bit line direction DB. In addition, the cover insulating film 10 may be configured by using, for example, a silicon oxide film. In addition, in the case where the cover insulating film 10 is formed on the control gate electrode 8, the condition of bad coverage may be set so that the air gaps AG2 and AG3 between the memory cells are not buried with the cover insulating film 10. At this time, in the drain side of the select gate transistor, the spacing between the select gate transistors is wider than the spacing between the select gate transistor and the memory cell. As a result, in the drain side of the select gate transistor, the cover insulating film 10 can be formed to be inserted therein. Therefore, while the air gaps AG2 and AG3 are formed, the air gap AG1 in the drain side of the select gate transistor can be buried with the cover insulating film 10.

At this time, in the air gap AG1, the cover insulating film 10 is grown within a range that raw gas reaches. In other words, the growing speed of the cover insulating film 10 is high at corner portions of the control gate electrode 8, and the cover insulating film 10 is grown in a substantially circular shape at corner portions of the control gate electrode 8. This is because the cover insulating film 10 is grown from both of the side and bottom surfaces of the control gate electrode 8. As a result, under the control gate electrode 8, the cover insulating film 10 is configured to have an inversely tapered shape which is far away from the memory cell side as it goes from the control gate electrode 8 to the back-filling insulating film 3.

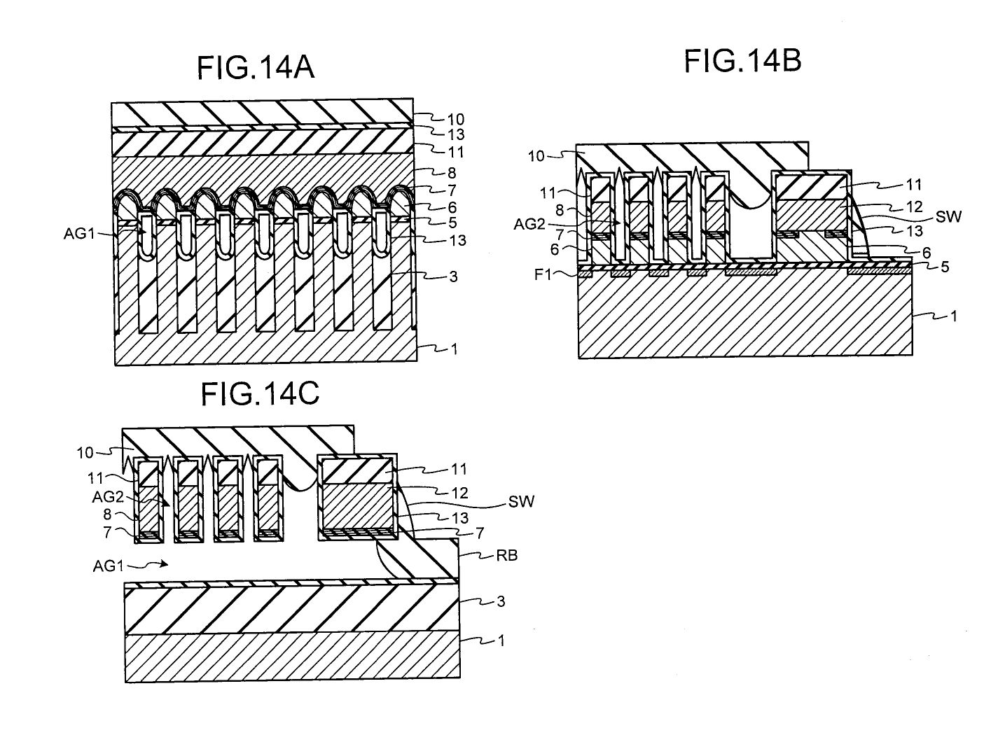

As illustrated in FIGS. 14A to 14C, by using a photolithography technique and an anisotropic etching technique, the cover insulating film 10 is removed so that the cover insulating film 10 remains in the side surface including the inner portion of the trench 2 between the drains of the select gate transistors. The air gap AG1 between the drains of the select gate transistors is back-filled with the back-filling insulating film RB, and a side wall SW is formed on the side surface of the select gate electrode 12.

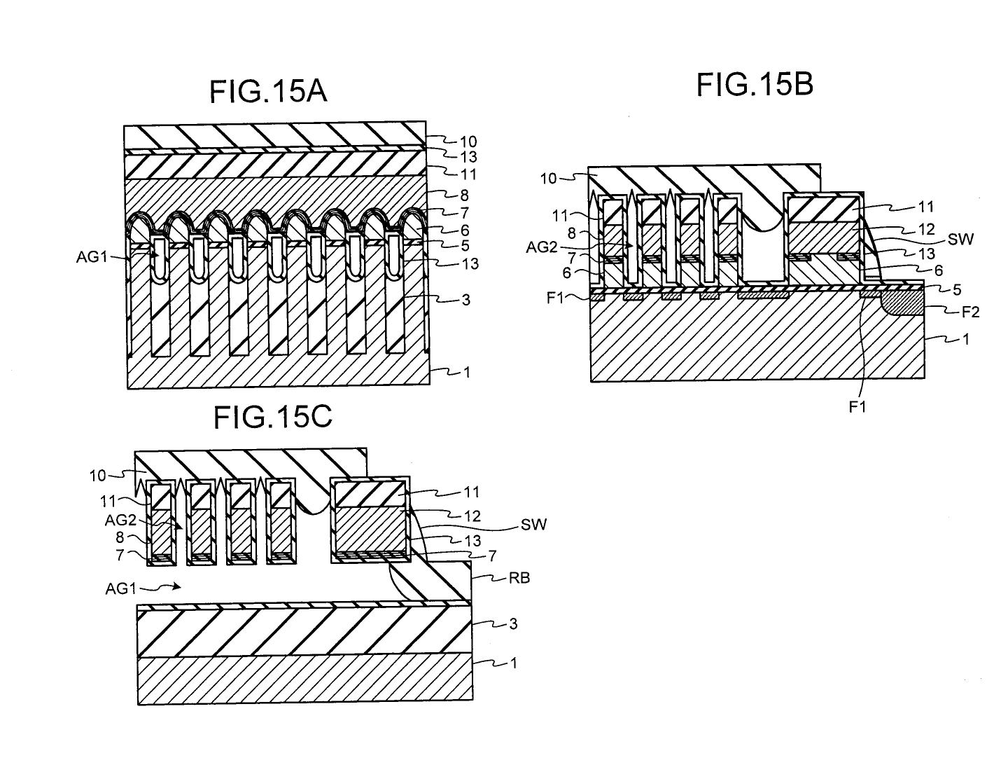

As illustrated in FIGS. 15A to 15C, a high-concentration diffusion layer F2 is formed on the drain region of the select gate transistor by selectively implanting impurity ions into the semiconductor substrate 1. The contact resistance of the bit line contact BC can be lowered by the high-concentration diffusion layer F2. In addition, in the drain side of the select gate transistor, the portion between the active areas AA is buried with the back-filling insulating film RB. As a result, little amount of impurities penetrates the back-filling insulating film RB and the back-filling insulating film 3 to reach the semiconductor substrate 1. As a result, in the drain side of the select gate transistor, the impurity concentration of the semiconductor substrate 1 between the active areas AA can be lowered.

After that, by using well-known methods, the silicide layer 9 and the bit line contact CB are formed, so that the semiconductor storage device according to the embodiment is completed.

### Fourth Embodiment

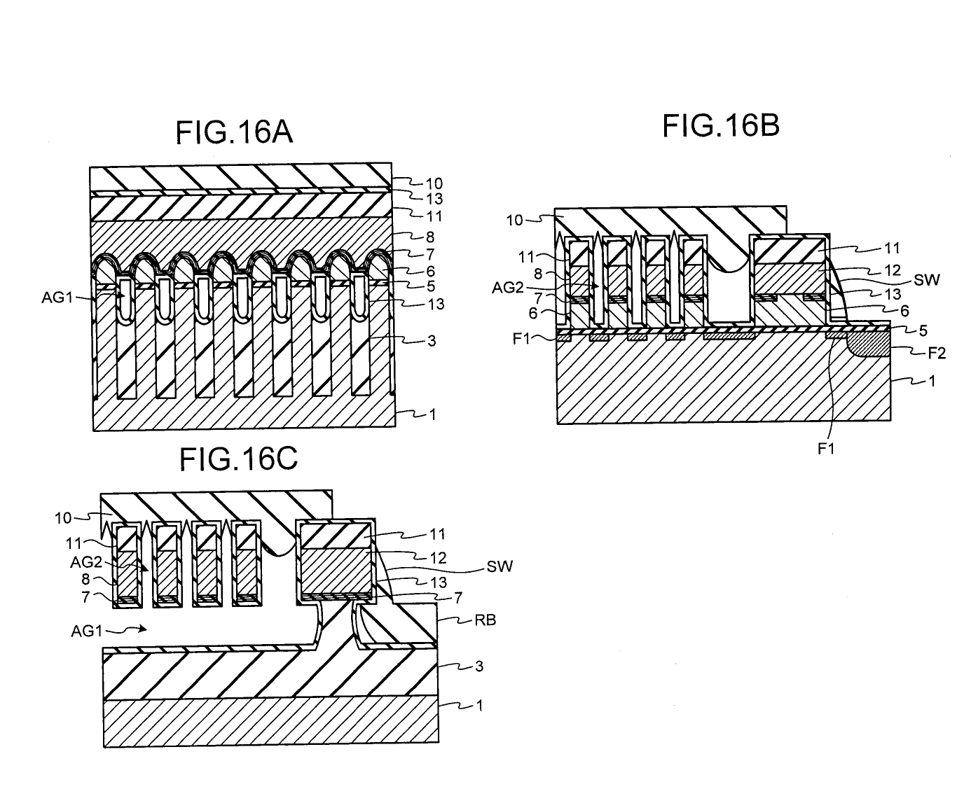

FIGS. 16A to 16C are cross-sectional diagrams illustrating a non-volatile semiconductor storage device manufacturing method according to a fourth embodiment as an example. In addition, FIGS. 16A to 16C respectively correspond to FIGS. 14A to 14C.

In the configuration illustrated in FIG. 14C, although the configuration where the air gap AG1 under the select gate electrode 12 is penetrated is described, the air gap AG1 under the select gate electrode 12 may be divided by the burying insulating film 3 as illustrated in FIG. 16C. This structure may be formed by adjusting the condition of the wet etching illustrated in FIG. 10.

### Fifth Embodiment

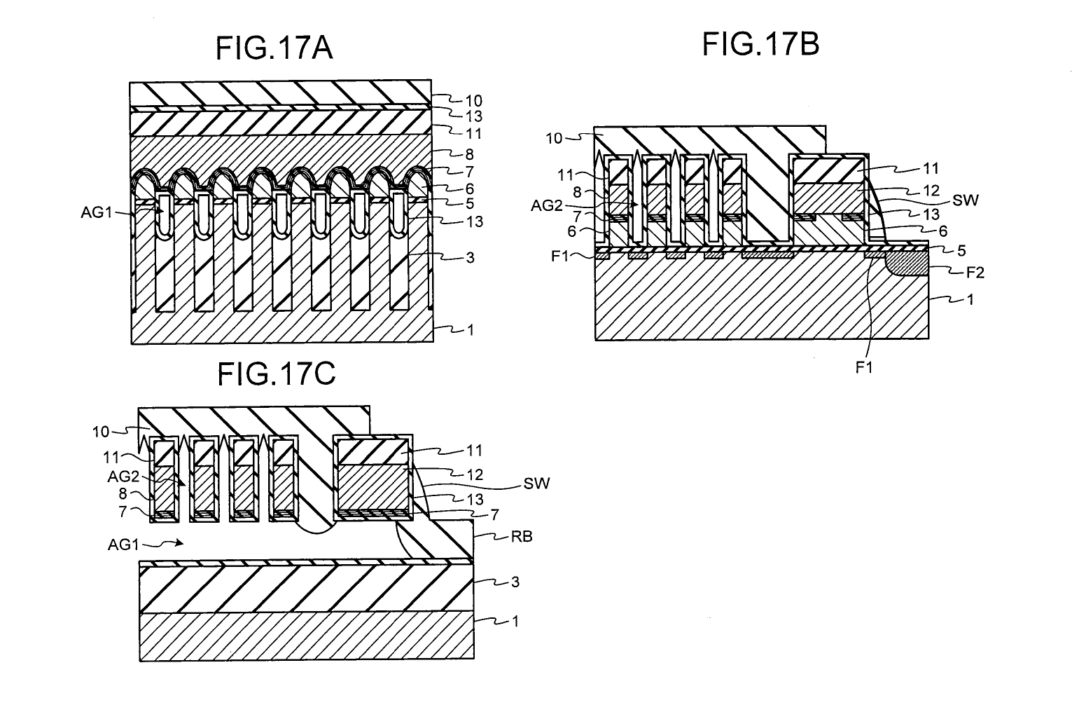

FIGS. 17A to 17C are cross-sectional diagrams illustrating a non-volatile semiconductor storage device manufacturing method according to a fifth embodiment as an example. In addition, FIGS. 17A to 17C respectively correspond to FIGS. 14A to 14C.

In the configuration illustrated in FIGS. 14B and 14C, although the method of forming the air gap AG3 between the charge storage layers 6 of the memory cell and the select gate transistor is described, the air gap AG3 between the charge storage layers 6 of the memory cell and the select gate transistor may be buried with the cover insulating film 10.

At this time, the spacing between the memory cell and the select gate transistor is wider than the spacing between the memory cells in the bit line direction DB. Therefore, the condition of coverage of the cover insulating film 10 can be set so that the air gap AG2 between the memory cells is not buried with the cover insulating film 10 but the air gap AG3 between the memory cell and the select gate transistor is buried the cover insulating film 10.

Herein, the air gap AG3 between the charge storage layers 6 of the memory cell and the select gate transistor is buried with the cover insulating film 10, so that fringe capacitance of the select gate transistor and the memory cell adjacent to the select gate transistor is increased. As a result, for example, during a read operation, an electric field can be easily transferred to the active area between the memory cell and the select gate transistor, so that it is possible to reduce a resistance of the active area AA. As a result, it is possible to increase read margin.

### Sixth Embodiment

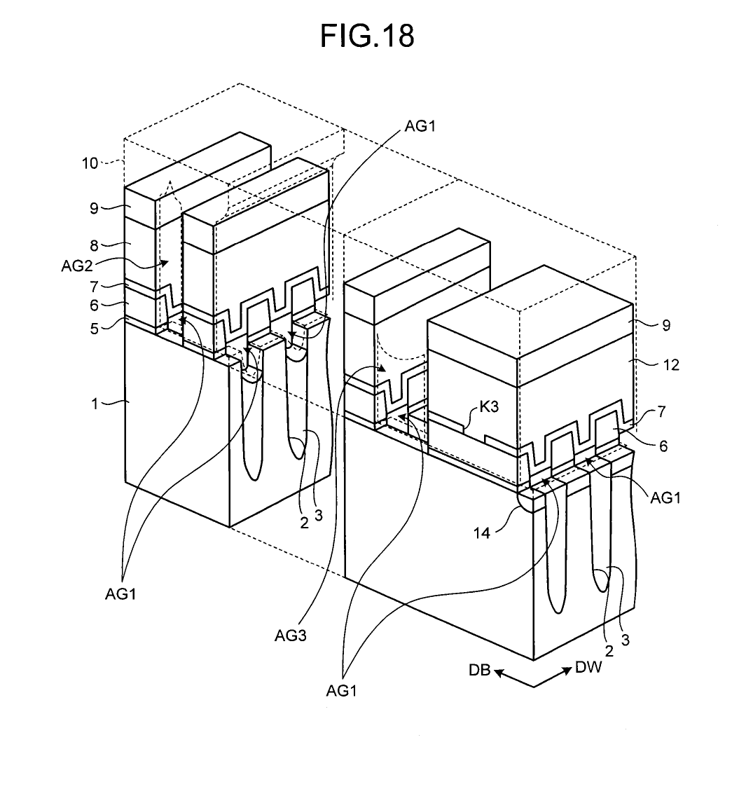

FIG. 18 is a schematic perspective diagram illustrating a configuration of memory cells and select gate transistors of a non-volatile semiconductor storage device according to a sixth embodiment.

In the configuration of FIG. 1, a method of forming the air gap AG1 continuously along the trench 2 so as to be concealed under the control gate electrode 8 and the select gate electrode 12 and back-filling the air gap AG1 by back-filling insulating film RB between the drain regions of the select gate transistors is described. On the other hand, as illustrated in FIG. 18, the air gap AG1 may be formed continuously along the trench 2 so as to be concealed under the control gate electrode 8 and the select gate electrode 12 while the air gap AG1 is not allowed to reach the portion between the drain regions of the select gate transistor. In other words, the end of the air gap AG1 is under the select gate electrode 12.

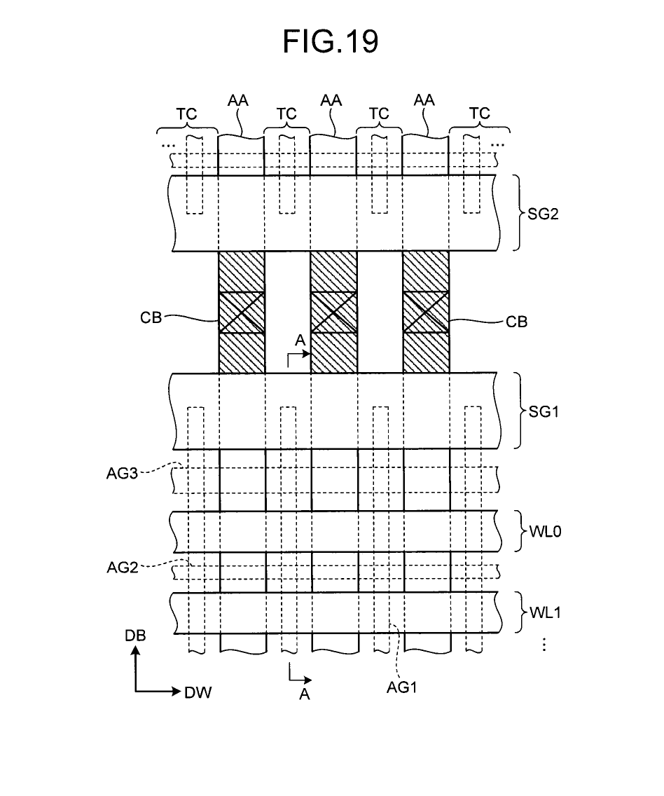

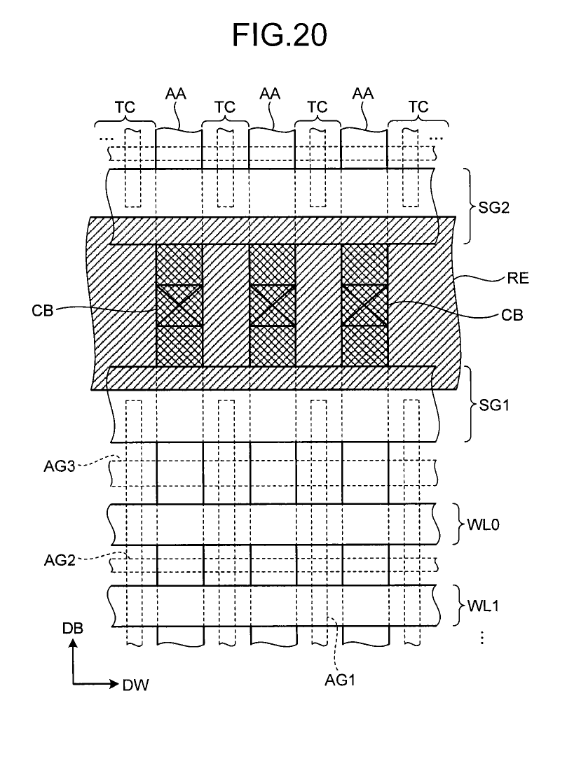

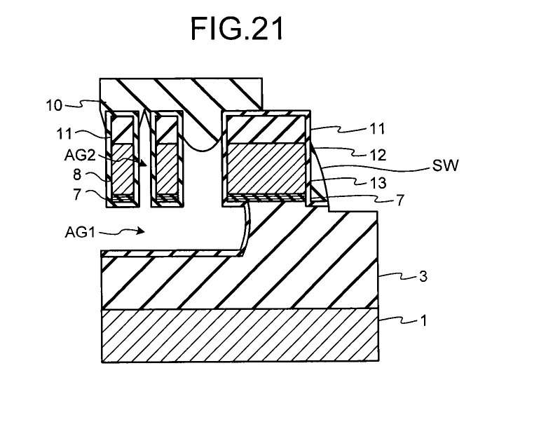

FIG. 19 is a schematic plan diagram illustrating an example of a configuration of a memory cell array of the non-volatile semiconductor storage device according to the sixth embodiment. FIG. 20 is a plan diagram illustrating a resist pattern arrangement method during formation of an air gap AG1 of FIG. 19 as an example. FIG. 21 is a cross-sectional diagram taken along line A-A of FIG. 19 as an example.

In FIG. 21, the portion between the drain regions of the select gate transistors is buried with the burying insulating film 3 in the bit line direction DB. In addition, the upper surface of the burying insulating film 3 may be higher or lower than the upper surface of the semiconductor substrate 1.

In FIG. 20, before the air gap AG1 is formed, a resist pattern RE covering the portion between the select gate electrodes SG1 and SG2 is formed on the semiconductor substrate 1. The burying insulating film buried in the trench TC is removed, so that the air gap AG1 is formed.

For example, after the processes of FIGS. 9A to 9C, a resist pattern RE covering the drain side of the select gate transistor is formed on the semiconductor substrate 1. In the processes of FIGS. 10A to 10C, a portion of the burying insulating film 3 is removed along the trench 2, so that the air gap AG1 is formed between the charge storage layers 6.

At this time, under the select gate electrode 12, etching proceeds from the source side of the select gate transistor, and etching does not proceed from the drain side of the select gate transistor. Therefore, before the air gap AG1 reaches the drain side of the select gate transistor, the etching of the burying insulating film 3 is stopped, so that it is possible to prevent the air gap AG1 from being formed in the drain side of the select gate transistor.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A non-volatile semiconductor storage device comprising:
a memory cell which is disposed on a semiconductor substrate and where a control gate electrode is disposed on a charge storage layer;
a select gate transistor where a select gate electrode is disposed between a source region and a drain region and which shares the source region with the memory cell;
a first air gap which is disposed between the charge storage layers and between the source regions adjacent to each other in a word line direction and which is formed continuously over the memory cell and the select gate transistor adjacent to each other in a bit line direction so as to be concealed under the word line and under the select gate electrode; and
a back-filling insulating film which back-fills an air gap between the drain regions adjacent to each other in the word line direction.

2. The non-volatile semiconductor storage device according to claim 1, wherein the first air gap is inserted into a trench formed in the semiconductor substrate which divides the active area of the memory cell.

3. The non-volatile semiconductor storage device according to claim 2, wherein the first air gap is formed continuously in the trench over the memory cell and the select gate transistor.

4. The non-volatile semiconductor storage device according to claim 3, wherein the control gate electrode and the select gate electrode extend in a direction perpendicular to the first air gap and are shared by the memory cell and the select gate transistor that are adjacent thereto.

5. The non-volatile semiconductor storage device according to claim 4, wherein the position of the bottom surface of the control gate electrode on the charge storage layer is higher than the position of the bottom surface of the control gate electrode on the first air gap.

6. The non-volatile semiconductor storage device according to claim 1, further comprising a second air gap which is formed between the charge storage layers adjacent to each other in the bit line direction, wherein
the first air gap is connected to the second air gap on the first air gap

7. A non-volatile semiconductor storage device comprising:
a memory cell where a control gate electrode is disposed on a charge storage layer;
a select gate transistor where a select gate electrode is disposed between a source region and a drain region and which shares the source region with the memory cell; and
a first air gap which is disposed between the charge storage layers and between the source regions adjacent to each other in a word line direction so as not to reach a portion between the drain regions adjacent to each other in the word line direction and which is formed continuously over the memory cell and the select gate transistor adjacent to each other in a bit line direction so as to be concealed under the word line and under the select gate electrode.

8. The non-volatile semiconductor storage device according to claim 7, wherein the first air gap is inserted into a trench formed in the semiconductor substrate which divides the active area of the memory cell.

9. The non-volatile semiconductor storage device according to claim 8, wherein the first air gap is inserted into a trench formed in the semiconductor substrate which divides the active area of the memory cell.

10. The non-volatile semiconductor storage device according to claim 9, wherein the control gate electrode and the select gate electrode are arranged to be perpendicular to the first air gap.

11. The non-volatile semiconductor storage device according to claim 10, wherein the position of the bottom surface of the control gate electrode on the charge storage layer is higher than the position of the bottom surface of the control gate electrode on the first air gap.

12. The non-volatile semiconductor storage device according to claim 7, further comprising a second air gap which is formed between the charge storage layers adjacent to each other in the bit line direction, wherein
the first air gap is connected to the second air gap on the first air gap

13. The non-volatile semiconductor storage device according to claim 7, wherein an end of the first air gap is under the select gate electrode.

14. A non-volatile semiconductor storage device comprising:
a memory cell which is disposed on a semiconductor substrate and where a control gate electrode is disposed on a charge storage layer;
a select gate transistor where a select gate electrode is disposed between a source region and a drain region and which shares the source region with the memory cell;
a first air gap which is disposed between the charge storage layers and between the source regions adjacent to each other in a word line direction and which is formed continuously over the memory cell and the select gate transistor adjacent to each other in a bit line direction so as to be concealed under the word line and under the select gate electrode;
a second air gap which is disposed between the charge storage layers adjacent to each other in a bit line direction; and
a cover insulating film which covers the second air gap so as not to be buried in the second air gap and which is buried in a portion between the select gate transistor and the memory cell adjacent to the select gate transistor.

15. The non-volatile semiconductor storage device according to claim 14, wherein an end of the first air gap is under the select gate electrode.

16. The non-volatile semiconductor storage device according to claim 14, wherein the first air gap is inserted into a trench formed in the semiconductor substrate which divides the active area of the memory cell.

17. The non-volatile semiconductor storage device according to claim 16, wherein the first air gap is inserted into a trench formed in the semiconductor substrate which divides the active area of the memory cell.

18. The non-volatile semiconductor storage device according to claim 17, wherein the control gate electrode and the select gate electrode are arranged to be perpendicular to the first air gap.

19. The non-volatile semiconductor storage device according to claim 18, wherein the position of the bottom surface of the control gate electrode on the charge storage layer is higher than the position of the bottom surface of the control gate electrode on the first air gap.
